(19) United States
(12) Patent Application Publication
(10) Pub. No.: US 2023/0115773 A1
(43) Pub. Date: Apr. 13, 2023

(54) DOORBELL SYSTEM AND METHOD FOR CONTROLLING DOORBELL SYSTEM

(71) Applicant: SAVANT TECHNOLOGIES LLC, East Cleveland, OH (US)

(72) Inventors: Weihu CHEN, Shanghai (CN); Jinpeng HU, Shanghai (CN); Hongbin XU, Shanghai (CN); Yang LU, Shanghai (CN); Dong XING, Shanghai (CN)

(73) Assignee: SAVANT TECHNOLOGIES LLC, East Cleveland, OH (US)

(21) Appl. No.: 17/956,467

(22) Filed: Sep. 29, 2022

(30) Foreign Application Priority Data
Sep. 30, 2021 (CN) 202111163361.4

(51) Int. Cl. H03K 17/94; H04B 3/54; G08B 3/10; G05B 19/02; H03K 17/18

(52) U.S. Cl. CPC H03K 17/94; G05B 19/02; G08B 3/10; H03K 17/18; H04B 3/54

(57) ABSTRACT

Disclosed are a doorbell system and a method for controlling a doorbell system that includes a shunt unit electrically connected to a signaling unit of a doorbell system, a power harvest unit electrically connected to the shunt unit and the signaling unit, a first switch unit, the power harvest unit being selectively connected to an external power source via the first switch unit, a button unit that receives a press operation, and a detection and control unit that detects whether there is a press operation, and controls the first switch unit to be in a first mode when no press operation is detected, the power harvest unit harvests power from the external power source via the first switch unit in the first mode, and controls the first switch unit to be in a second mode and controls the signaling unit to make sound when the press operation is detected.

### CROSS-REFERENCE TO RELATED APPLICATIONS

This application claims the benefit of Chinese Patent Application Serial Number 202111163361.4, filed Sep. 30, 2021, which is herein incorporated by reference.

### DESCRIPTION

### Field of Technology

The present disclosure relates generally to a communication device and method, and more particularly, to a doorbell system and a method for controlling a doorbell system.

### BACKGROUND

Traditional doorbells are usually installed at a door of a house, and such traditional doorbells are connected to an indoor chime by means of wires. When the visitor presses the button of the doorbell, bell voice is made by the indoor chime to inform the owner of the visitor.

Traditional doorbell systems typically comprise one or more doorbell buttons. As shown in FIG. 1, doorbell buttons 102, 104 are connected in series with output ends of a chime 108 and a transformer 106. In addition, an input end of the transformer 106 is connected to a mains supply. When a user presses the button 102 or 104, power is supplied to the chime 108 such that the chime makes bell voice. The chime 108 may generally comprise a mechanical chime and an electronic chime.

Although the traditional doorbell system has the advantages of simple installation and operation, it only has the single function of notification by sound and does not have any other additional functions, and therefore cannot meet people’s requirements for multiple functions and security of doorbells gradually in practical use.

It has been proposed to replace a traditional doorbell button with a smart doorbell system. A smart doorbell system adopts a smart unit. The smart unit generally comprises an electronic switch (button), a switch power source and/or rechargeable battery management, a wireless module, a video module and an audio module. However, it is still challenging for the smart unit to achieve good compatibility with traditional chimes. Moreover, how to reduce the requirements for a large-capacity rechargeable battery without affecting the normal operation of a doorbell system is also a problem to be solved.

### SUMMARY

In view of this, the present disclosure provides a doorbell system and a method for controlling a doorbell system, which can achieve good compatibility with a traditional chime while reducing the requirements for a large-capacity rechargeable battery.

According to an embodiment of the present disclosure, a doorbell system is provided. The doorbell system comprises: a shunt unit electrically connected to a signaling unit of the doorbell system; a power harvest unit electrically connected to the shunt unit and the signaling unit; a first switch unit, the power harvest unit being selectively connected to an external power source by means of the first switch unit; a button unit configured to receive a press operation of a user; and a detection and control unit configured to detect whether the button unit receives the press operation, wherein the detection and control unit is further configured such that in the case where the detection and control unit does not detect the press operation, the detection and control unit controls the first switch unit such that the first switch unit is in a first mode, and the power harvest unit harvests power from the external power source by means of the first switch unit in the first mode; and in the case where the detection and control unit detects the press operation, the detection and control unit controls the first switch unit such that the first switch unit is in a second mode, and controls the signaling unit to make sound.

Preferably, the doorbell system further comprises a second switch unit, and in the case where the button unit receives the press operation of the user, the second switch unit is in an on state, meanwhile the detection and control unit detects the real time state of the press operation in real time, and the detection and control unit controls the power of the external power source to flow through the signaling unit and the shunt unit, such that the maximum duration of the current is controlled while the signaling unit makes sound.

Preferably, the second switch unit comprises at least one of an electronic switch and a mechanical switch.

Preferably, the signaling unit is a mechanical signaling unit or an electronic signaling unit.

Preferably, the shunt unit comprises a shunt circuit module, and the shunt circuit module comprises at least one of a resistor, a capacitor, and a diode.

Preferably, the detection and control unit controls the turn-on/ turn-off of the first switch unit by means of a PWM signal control method.

Preferably, in the first mode, the first switch unit is in a power harvest mode, and in the second mode, the first switch unit is in a ringing mode.

According to another embodiment of the present disclosure, a method for controlling a doorbell system is provided. The method for controlling a doorbell system comprises: detecting, by a detection and control unit, whether a button unit of a doorbell system receives a press operation of a user; and detecting, by the detection and control unit, the real time state of the press operation in real time and whether there is a power supply from an external power source, wherein in the case where the detection and control unit does not detect the press operation, the detection and control unit enables a first switch unit of the doorbell system to be in a first mode, and a power harvest unit of the doorbell system harvests power from the external power source by means of the first switch unit in the first mode; and in the case where the detection and control unit detects the press operation, the detection and control unit enables the first switch unit to be in a second mode, and controls a signaling unit to make sound.

From the described solutions, it can be seen that due to a special method (including hardware design and control logic design) adopted by the present disclosure in the power stage of smart unit of the doorbell system, good compatibility with a traditional chime is achieved, and the normal power supply to the smart unit is maintained without providing a rechargeable battery, thereby reducing manufacturing and usage costs.

### BRIEF DESCRIPTION OF THE DRAWINGS

The preferred embodiments of the present disclosure will be illustrated hereinafter in detail with reference to the accompany drawings, so as to make those skilled in the art understand the above and other features and merits of the present disclosure clearly, in the drawings:

FIG. 1 is a schematic diagram of a traditional doorbell system.

FIG. 2 is a schematic block diagram of a doorbell system according to an embodiment of the present disclosure.

FIG. 3 is a schematic circuit diagram of the doorbell system shown in FIG. 2.

FIG. 4 is a flowchart of a method for controlling a doorbell system according to an embodiment of the present disclosure.

### DETAILED DESCRIPTION

To make the objects, technical solutions, and advantages of the present disclosure clearer, the present disclosure will be further described in detail with reference to the embodiments.

It should be noted that the embodiments and the features in the embodiments of the present disclosure may be combined without conflicts. The present disclosure will be described below with reference to the drawings and embodiments in detail.

It is noted that, unless otherwise indicated, all technical and scientific terms used herein have the same meaning as commonly understood by one of ordinary skill in the art to which the present disclosure belongs.

In the present disclosure, unless specified to the contrary, the orientation terms such as “upper, lower, top and bottom” are generally used for the directions shown in the drawings, or for the vertical, perpendicular or gravitational directions of components themselves. Likewise, for ease of understanding and description, “interior and exterior” refers to the interior and exterior relative to the contour of each component itself, but the foregoing orientation terms are not intended to limit the present disclosure.

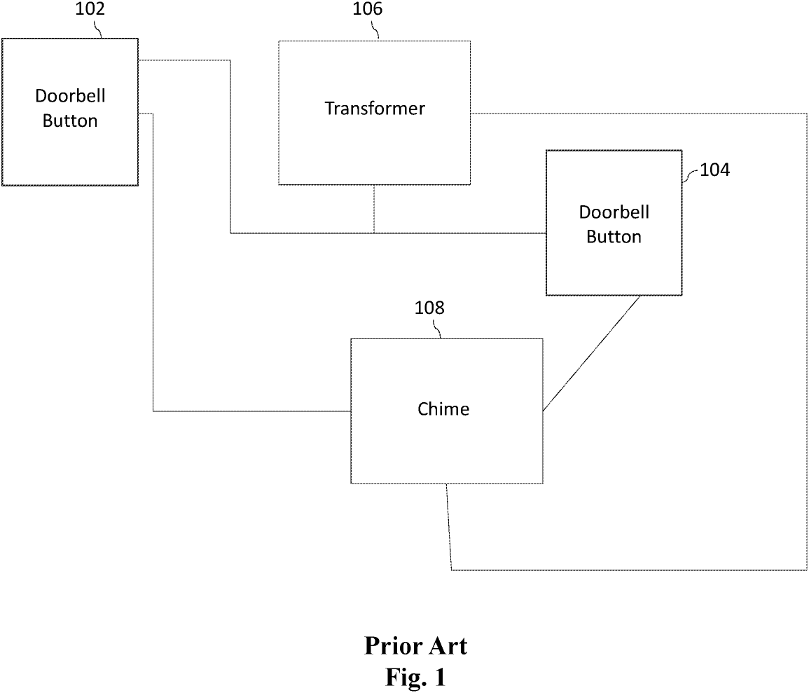

As shown in FIG. 1, doorbell buttons 102, 104 are connected in series with output ends of a chime 108 and a transformer 106. In addition, an input end of the transformer 106 is connected to a household AC power source. When a user presses the button 102 or 104, power is supplied to the chime 108 by means of the transformer 106 such that the chime makes bell voice. The chime 108 may generally comprise a mechanical chime and an electronic chime. For example, when the user presses the button 102 or 104, the chime 108 in the house is activated. Pressing the button 102 or 104 temporarily closes the doorbell circuit, and the doorbell circuit may be, for example, a single-pole single-throw (SPST) button switch, and as shown in FIG. 1, one terminal of each of the buttons 102, 104 is connected to an output terminal of the transformer 106. The transformer 106 reduces the household AC power source at 120 volts or 240 volts to a lower voltage, typically 8 volts to 24 volts. The other terminal of the transformer 106 is connected to a terminal of the chime 108. The other terminal of the chime 108 is connected to the other terminal of each of the buttons 102, 104. One common signaling device comprises two flat metal strip resonators that are hit by two solenoid operated plungers. The flat bars are adjusted to different notes. When the button 102 or 104 is pressed, the plunger of the first solenoid hits one of the metal flat bars, and when the button is released, a spring on the plunger pushes the plunger upward, so that the plunger hits the other metal flat bar to make a dual-tone sound (“ding-dong”).

Currently, the doorbell system with multiple functions is generally less compatible with the traditional doorbell system described in FIG. 1. One of the reasons for the incompatibility is that the power harvested from the household AC power source by the doorbell system having an A/V recording function is higher than a threshold required to enable the chime to make sound. Therefore, the doorbell system having an A/V recording function may cause the chime to frequently and unintentionally make sound, which not only troubles the residents, but also deteriorates the effectiveness of the doorbell.

According to the embodiments of the present disclosure, by connecting a power unit in parallel to a chime, unintentional sounding of the chime is avoided, and compatibility with an existing household AC power source and an existing chime can be achieved. In addition, in the embodiments of the present disclosure, the battery is not relied on as a primary (or unique) power source, and the normal power supply to the various units of the doorbell system is achieved by means of a high-frequency power harvest module.

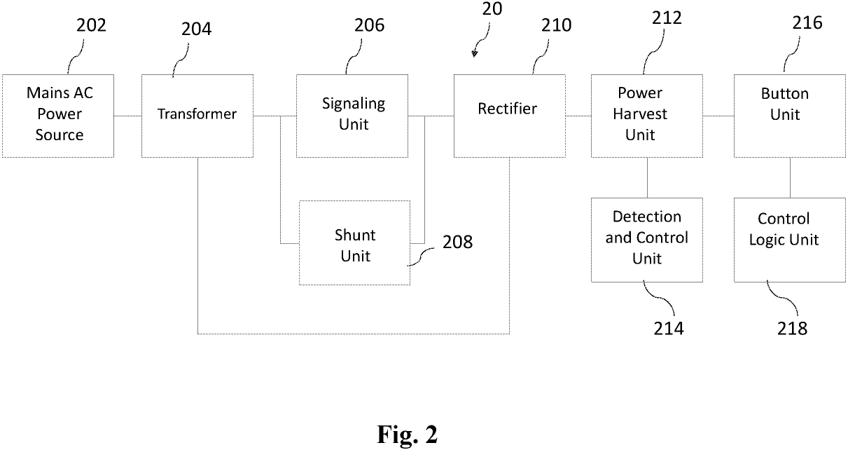

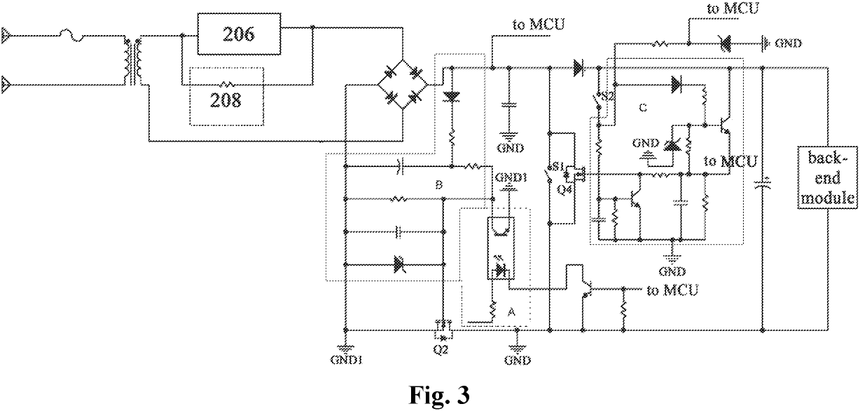

FIG. 2 is a schematic block diagram of a doorbell system according to an embodiment of the present disclosure. As shown in FIG. 2, the doorbell system 20 comprises: a transformer 204, wherein an input end of the transformer 204 is connected to a mains AC power source 202, and the transformer 204 reduces a received AC power source to a lower voltage, typically 16 volts to 24 volts; a signaling unit 206, wherein one end of the signaling unit 206 is connected to an output end of the transformer 204; a shunt unit 208, wherein the shunt unit 208 is connected in parallel to the signaling unit 206, and the shunt unit includes at least a symmetrical load bypass device or circuit module, for example, the shunt circuit module comprises at least one of a resistor and a capacitor, and the shunt unit may also include an asymmetrical load bypass device or circuit module, for example, the shunt circuit module comprises a diode or a transistor, the shunt unit 208 can shunt a current flowing through the signaling unit 206, so as to avoid causing unintentional sounding of the signaling unit 206, that is, the shunt unit 208 facilitates the doorbell system 20 harvesting power from the AC power source 202 without inadvertently triggering the signaling unit 206; a rectifier unit 210 configured to rectify a current from the transformer 204, wherein for example, the rectifier unit 210 may be a full-bridge rectification circuit composed of four diodes; a high-frequency power harvest unit 212 configured to harvest power from the AC power source 202 by means of the rectifier unit 210; a button unit 216 configured to receive a press operation of a user; a control logic unit 218 configured to control the button unit 216; and a detection and control unit 214, wherein the detection and control unit 214 controls the high-frequency power harvest unit 212 by means of a PWM signal control method, for example, the detection and control unit 214 may be a micro control unit (MCU), which detects whether the button unit 216 receives the press operation and whether there is a power input from the AC power source 202, and in the case where the detection and control unit 214 does not detect the press operation, the detection and control unit 214 limits the switching frequency by supplying a high frequency signal, and controls a first switch unit in the high-frequency power harvest unit 212 such that the first switch unit is in a power harvest state (for example, the first switch unit is Q2 as shown with reference to FIG. 3, and in the power harvest state, Q2 may be in an on/off state), and the high-frequency power harvest unit 212 harvests power from the AC power source 202 by means of the first switch unit in the power harvest state; and in the case where the detection and control unit 214 detects the press operation (for example, in the case where the button unit 216 receives the press operation from the user, S1 or Q4+S2 as shown with reference to FIG. 3 is enabled to be in an on state, and thus the detection and control unit 214 detects that there is a power input from the AC power source 202), the detection and control unit 214 controls the first switch unit such that the first switch unit is in a ringing state, and controls the power of the AC power source 202 to flow through the signaling unit 206 and the shunt unit 208, such that the signaling unit 206 makes sound. In addition, the doorbell system 20 may further comprise a PSU (Power Supply Unit) and other back-end modules as is known to those skilled in the art.

Hereinafter, an example of a circuit design of the doorbell system of the present disclosure will be explained with reference to FIG. 3. FIG. 3 is a schematic circuit diagram of the doorbell system shown in FIG. 2, and like elements are designated by like reference numerals. As shown in FIG. 3, a shunt unit 208 (i.e., power kit) is connected in parallel to a signaling unit 206. In FIG. 3, a resistor is used as the shunt unit 208. In addition, a capacitor, a diode, etc. may also be used as the shunt unit 208. An electronic switch Q2 is controlled by an MCU in an isolated manner (as stated above, the electronic switch Q2 may be implemented as a first switch unit), so as to control a power harvest operation. The so-called isolation manner is that the MCU drive control signal is isolated from the drive signal of Q2. Such isolation is at least achieved by an optical coupler (box A) in FIG. 3. That is, as shown in FIG. 3, by providing the signals at the respective circuit nodes shown to the MCU, the MCU can detect the states of the respective elements of the doorbell system in real time. S1, or S2 and Q4 (as stated above, S1, or S2 and Q4 may be implemented as a second switch unit) are used as traditional doorbell buttons. S1 could be a mechanical switch. Preferably, S2 and Q4 are adopted. S2 can be a signal tact switch, which is relatively light and easy to install on the doorbell. Q4 may be soft triggered by S2. S2 and Q4 are self-controlled completely by pure analog circuits and are still controlled by the MCU. The MCU detects whether S1 or S2 is pressed, and detects input of an AC power source. When S1 or S2 is off, that is, there is no press operation, the MCU controls Q2 to be in a power harvest state, so as to achieve high-frequency power harvesting. When S1 or S2 is on, that is, there is a press operation, the MCU detects the real time state of the press operation in real time, and then controls Q2 to be in a ringing state, so as to control a current inputted by the AC power source to flow through the signaling unit 206 and the shunt unit 208, such that the maximum duration of the current is controlled while the signaling unit 206 makes sound. Furthermore, at the time of initial conduction of power, Q2 is in an automatic on state. In order to achieve compatibility with a traditional doorbell system, the duration of Q2 in a power harvest state or in a ringing state will be strictly set depending on the application scenario. In addition, in the case where the doorbell system adopts the tact mechanical switch S2 and the electronic switch Q4, in order to prevent the doorbell button from being pressed for a long time to cause Q4 turn on for too long and thus generate heat and being damaged, the duration of Q2 in the ringing state when the doorbell button is pressed may be limited. Therefore, as shown in FIG. 3, a pure analog circuit (box C), which including at least a third switch unit and a fourth switch unit, is also designed to limit the maximum turn-on duration of Q4. When the on-time of Q4 reaches the maximum turn-on duration, Q4 is self-locked and disconnected. Preferably, the limit control of the turn-on duration can also be realized by digital control of the MCU. In the case where the mechanical switch S1 is adopted, the mechanical switch S1 has strong resistance to electricity, and there is no problem of damage when pressed for a long time.

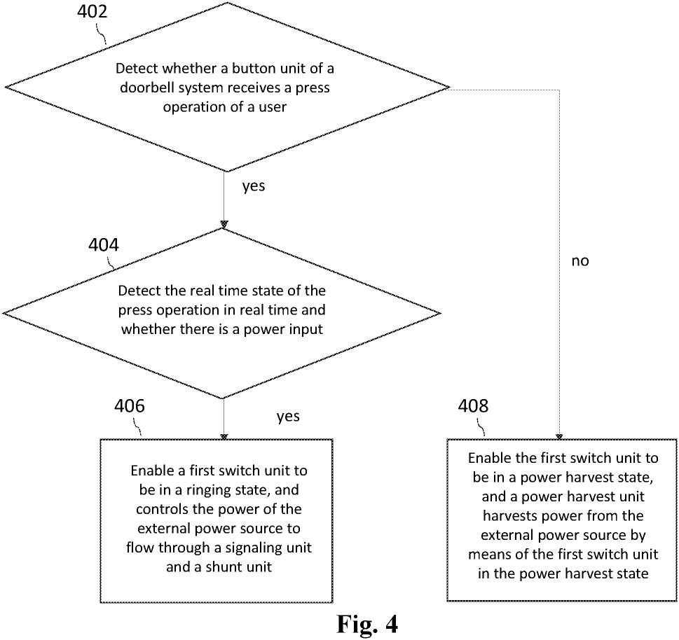

FIG. 4 is a flowchart of a method for controlling a doorbell system according to an embodiment of the present disclosure. The method comprises: Step 402: a detection and control unit detects whether a button unit of a doorbell system receives a press operation of a user; Step 404: the detection and control unit detects the real time state of the press operation in real time and whether there is a power input from an external power source; Step 406: in the case where both determination results in Step 402 and Step 404 are yes, the detection and control unit enables a first switch unit to be in a ringing state, and controls the power of the external power source to flow through a signaling unit and a shunt unit of the doorbell system, such that the signaling unit makes sound; and Step 408: in the case where the detection and control unit does not detect the press operation in step 402, the detection and control unit enables the first switch unit of the doorbell system to be in a power harvest state, and a power harvest unit of the doorbell system harvests power from the external power source by means of the first switch unit in the power harvest state.

From the described solutions, it can be seen that due to a special method (including hardware design and control logic design) adopted by the present disclosure in the power stage of smart unit of the doorbell system, good compatibility with a traditional chime is achieved, and false triggering of the chime is avoided. In addition, the normal power supply to the smart unit is maintained without providing a rechargeable battery, thereby reducing manufacturing and usage costs.

Moreover, the smart doorbell system of the present disclosure has a simple manufacturing process and is easy to install. The smart doorbell of the present disclosure provides additional components without requiring, for example, energy storage device, relaying device, signaling device, and current sensing device. Furthermore, manufacturing costs are further reduced by using a shunt resistor and eliminating the need for complex components.

The foregoing descriptions are merely preferred embodiments of the present disclosure, and are not intended to limit the present disclosure. Any modification, equivalent replacement, or improvement made within the spirit and principle of the present disclosure shall be included within the scope of protection of the present disclosure.

What we claim is:

1. A doorbell system, comprising:
a signaling unit;
a shunt unit electrically connected to the signaling unit of the doorbell system;
a power harvest unit electrically connected to the shunt unit and the signaling unit;
a first switch unit, the power harvest unit being selectively connected to an external power source by means of the first switch unit;
a button unit configured to receive a press operation of a user; and
a detection and control unit configured to detect whether the button unit receives the press operation,
wherein the detection and control unit is further configured to:
in the case where the detection and control unit does not detect the press operation, the detection and control unit controls the first switch unit such that the first switch unit is in a first mode, and the power harvest unit harvests power from the external power source by means of the first switch unit in the first mode; and
in the case where the detection and control unit detects the press operation, the detection and control unit controls the first switch unit such that the first switch unit is in a second mode, and controls the signaling unit to make sound.

2. The doorbell system according to claim 1, wherein the doorbell system further comprises a second switch unit, and in the case where the button unit receives the press operation of the user, the second switch unit is in an on state, and the signaling unit makes sound.

3. The doorbell system according to claim 2, wherein the second switch unit comprises at least one of an electronic switch and a mechanical switch.

4. The doorbell system according to claim 3, wherein the second switch unit comprises an electronic switch, and in the case where the button unit receives the press operation of the user, the second switch unit is in an on state, meanwhile the detection and control unit detects the real time state of the press operation in real time, and the detection and control unit controls the power of the external power source to flow through the signaling unit and the shunt unit, such that the maximum duration of the current of the external power source is controlled while the signaling unit makes sound.

5. The doorbell system according to claim 3, further comprising a pure analog circuit, the pure analog circuit includes at least a third switch unit and a fourth switch unit, and the pure analog circuit controls the maximum turn-on duration of the electronic switch.

6. The doorbell system according to claim 1, wherein the signaling unit is a mechanical signaling unit or an electronic signaling unit.

7. The doorbell system according to claim 1, wherein the shunt unit includes at least a symmetrical load bypass device.

8. The doorbell system according to claim 7, wherein the symmetrical load bypass device comprises a resistor, or a capacitor.

9. The doorbell system according to claim 1, wherein the detection and control unit controls the on/off of the first switch unit by means of a PWM signal control method.

10. The doorbell system according to claim 9, wherein the PWM signal is a high frequency signal.

11. The doorbell system according to claim 1, the doorbell system further comprises an isolation drive circuit, the isolation drive circuit includes at least one optical coupler, and the isolation drive circuit controls the first switch unit at high frequency in an isolation drive manner.

12. The doorbell system according to claim 1, wherein in the first mode, the first switch unit is in a power harvest mode, and in the second mode, the first switch unit is in a ringing mode.

13. A doorbell system, comprising:
a signaling unit;
a shunt unit electrically connected to the signaling unit of the doorbell system;
a power harvest unit electrically connected to the shunt unit and the signaling unit;
a first switch unit, the power harvest unit being selectively connected to an external power source by means of the first switch unit;
a button unit configured to receive a press operation of a user; and
a detection and control unit configured to detect whether the button unit receives the press operation,
wherein the detection and control unit is further configured to:
in the case where the detection and control unit does not detect the press operation, the detection and control unit controls the first switch unit such that the first switch unit is in a first mode, and the power harvest unit harvests power from the external power source by means of the first switch unit in the first mode; and
in the case where the detection and control unit detects the press operation, the detection and control unit controls the first switch unit such that the first switch unit is in a second mode, and controls the signaling unit to make sound,
wherein the shunt unit includes at least a symmetrical load bypass device,
wherein the power harvest unit is a high-frequency power harvest unit, and the high-frequency of high-frequency power harvest unit is controlled by a micro control unit (MCU).

14. A method for controlling a doorbell system, comprising:
detecting, by a detection and control unit, whether a button unit of a doorbell system receives a press operation of a user; and
detecting, by the detection and control unit, the real time state of the press operation in real time and whether there is a power input from an external power source,
wherein
in the case where the detection and control unit does not detect the press operation, the detection and control unit enables a first switch unit of the doorbell system to be in a first mode, and a power harvest unit of the doorbell system harvests power from the external power source by means of the first switch unit in the first mode; and
in the case where the detection and control unit detects the press operation, the detection and control unit enables the first switch unit to be in a second mode, and controls a signaling unit of the doorbell system to make sound.

15. The method according to claim 14, wherein the doorbell system further comprises a second switch unit, and in the case where the button unit receives the press operation of the user, the second switch unit is in an on state.

16. The method according to claim 15, wherein the second switch unit comprises at least one of an electronic switch and a mechanical switch.

17. The method according to claim 16, wherein the maximum turn-on duration of the electronic switch is controlled by a pure analog circuit, and the pure analog circuit includes at least a third switch unit and a fourth switch unit.

18. The method according to claim 15, wherein the detection and control unit controls the on/off of the first switch unit by means of a PWM signal control method.

19. The method according to claim 18, wherein the PWM signal is a high frequency signal.

20. The method according to claim 14, the doorbell system further comprises an isolation drive circuit, the isolation drive circuit includes at least one optical coupler, and the isolation drive circuit controls the first switch unit at high frequency in an isolation drive manner.
